(19) United States
(12) Patent Application Publication
(10) Pub. No.: US 2022/0352417 A1
(43) Pub. Date: Nov. 3, 2022

(54) EMITTER SYSTEM ASSEMBLY AND METHOD OF FORMING

(71) Applicant: Raxium, Inc., Fremont, CA (US)

(72) Inventors: Gang He, Cupertino, CA (US); Emel Tasyurek, Santa Clara, CA (US); Michael Joseph Cich, San Jose, CA (US); Tarek Suwwan de Felipe, Los Altos, CA (US)

(21) Appl. No.: 17/732,290

(22) Filed: Apr. 28, 2022

Related U.S. Application Data
(60) Provisional application No. 63/254,959, filed on Oct. 12, 2021.
(60) Provisional application No. 63/180,840, filed on Apr. 28, 2021.

(51) Int. Cl. H01L 33/10; H01L 33/00; H01L 33/60

(52) U.S. Cl. CPC H01L 33/105; H01L 33/005; H01L 33/60; H01L 2933/0058

(57) ABSTRACT

An emitter system assembly includes an emitter providing a light emission, a cavity at least partially surrounding the emitter, an aperture configured for transmitting therethrough at least a portion of the light emission from the emitter, and a lenslet in optical communication with the aperture. The cavity includes reflectors for reflecting the light emission within the cavity and toward the aperture. Further, the cavity, the aperture, and the lenslet are configured to cooperate to produce the light output having optical properties suitable for coupling into a projector. In a further aspect, the optical properties include at least one of a predetermined output direction and a solid angle. In another aspect, the emitter system includes a low-refractive index material, anti-reflective layer, and/or light containment structures around the emitter.

### CROSS-REFERENCE TO RELATED APPLICATIONS

This application benefits from and claims priority to U.S. provisional patent application Ser. Nos. 63/180,840 filed Apr. 28, 2021 and 63/254,959 filed Oct. 12, 2021. The disclosure of each of these applications is incorporated herein by reference in its entirety.

### BACKGROUND

Aspects of the present disclosure generally relate to light emitting diodes (LEDs), and more specifically, to assemblies that enhance light extraction from micro light emitting diodes (microLEDs).

Recent advances in light emitting diode (LED) technologies have enabled the formation of high density display devices incorporating arrays of microLEDs, with each microLED having an emitter pitch on the order of a few microns to a fraction of a micron. For example, WO 2019209945 A1 discloses various configurations of microLED-based light field displays.

To illustrate the contrast between conventional and microLED-based displays, FIG. 1 shows a conventional display 110 having an array 120 of light emitting elements 125, as better seen in an inset 130. Light emitting elements 125, which may be traditional LEDs as discussed above, may all emit light at the same wavelength, or be arranged in patterns of LEDs emitting at two or more wavelengths. For example, array 120 may include LEDs emitting at red, green, and blue wavelengths in the visible spectrum, and arranged in a regular pattern.

In the example shown in FIG. 1, light emitting elements 125 may be arranged in a Q×P array over the area of display 110, with Q being the number of rows of light emitting elements 125 in the array and P being the number of columns of light emitting elements 125 in the array. Though not shown, conventional display 110 may include, in addition to light emitting elements 125, a backplane that includes various electrical traces and contacts configured to selectively deliver power to one or more of light emitting elements 125.

FIG. 2 shows a light field display 210 having an array 220 of super-raxels 225, as shown in a first inset 230. Further, each super-raxel 225, as shown in a second inset 240, includes sub-raxels 245. Each one of sub-raxels 245 may be a microLED, as described above. That is, each super-raxel 225 may correspond in size with a light emitting element 125 of FIG. 1, while including a plurality of sub-raxels 245 formed of microLEDs with emitter pitch of a few microns or even a fraction of a micron. In the example shown in FIG. 2, each super-raxel 225 is shown as having a generally square shape with each side having a super-raxel pitch 227. Each super-raxel 225 may be configured for emitting light at a single wavelength range (e.g., a red, green, or blue wavelength range) or over a range of colors (e.g., over at least a portion of the visible electromagnetic wavelength range).

In the example shown in FIG. 2, super-raxels 225 are arranged an N×M array, with N being the number of rows of super-raxels 225 in the array and M being the number of columns of super-raxels 225 in the array. As shown in FIG. 2, each one of super-raxels 225 includes a plurality of sub-raxels 245. Each one of sub-raxels 245 may include a microLED emitting at red, green, or blue wavelength in the visible spectrum, for example, and arranged in a regular pattern. In an example, sub-raxels 245 of different colors may be monolithically integrated on a common substrate, and each one of the microLEDs in a sub-raxel 245 may range in size from a fraction of 1 micron to approximately 100 microns.

FIG. 3 shows the light steering aspects of super-raxels 225. As shown in inset 330, each one of super-raxels 225 may include a light steering optical element 340. In the example illustrated in FIG. 3, each light steering optical element 340 is shown as having a lens pitch 345 on the order of the size of one of super-raxel 225.

While microLED-based displays enable new applications, various improvements are still possible to maximize the performance of each microLED and the display as a whole. In particular, compact microLED arrays for augmented reality/virtual reality (AR/VR) and other near-eye display applications require high brightness light output with highly efficient light extraction.

### SUMMARY OF THE EMBODIMENTS

The following presents a simplified summary of one or more aspects in order to provide a basic understanding of such aspects. This summary is not an extensive overview of all contemplated aspects and is intended to neither identify key or critical elements of all aspects nor delineate the scope of any or all aspects. Its purpose is to present some concepts of one or more aspects in a simplified form as a prelude to the more detailed description that is presented later.

In an aspect of the disclosure, an emitter system assembly for providing a light output for a projector is disclosed. The emitter system assembly includes an emitter providing a light emission, a cavity at least partially surrounding the emitter, an aperture configured for transmitting therethrough at least a portion of the light emission from the emitter, and a lenslet in optical communication with the aperture, The cavity includes reflectors for reflecting the light emission within the cavity and toward the aperture. Further, the cavity, the aperture, and the lenslet are configured to cooperate to produce the light output having optical properties suitable for coupling into the projector.

In a further aspect of the disclosure, the optical properties include at least one of a predetermined output direction and a solid angle.

In another aspect of the disclosure, an emitter system assembly for providing a light output for a projector includes a first emitter providing a first light emission, a second emitter providing a second light emission, a first cavity at least partially surrounding the first emitter, a second cavity at least partially surrounding the second emitter, a first aperture configured for transmitting therethrough at least a portion of the first light emission from the first emitter, a second aperture configured for transmitting therethrough at least a portion of the second light emission from the second emitter, and a lenslet in optical communication with the first and second apertures. The first cavity includes first reflectors for reflecting the first light emission within the first cavity and toward the first aperture. The second cavity includes second reflectors for reflecting the second light emission within the second cavity and toward the second aperture. Further, the first cavity, the first aperture, the second cavity, the second aperture, and the lenslet are configured to cooperate to produce the first and second light emission to contribute to the light output having optical properties suitable for coupling into the projector.

In still another aspect of the disclosure, an emitter system assembly for providing light output for a projector includes a first emitter providing a first light emission, a second emitter providing a second light emission, a cavity at least partially surrounding the first and second emitters, an aperture configured for transmitting therethrough at least a portion of the first and second light emission from the first and second emitters, and a lenslet in optical communication with the aperture. The cavity includes reflectors for reflecting the first and second light emissions within the cavity and toward the aperture. Further, the cavity, the aperture, and the lenslet are configured to cooperate to produce the light output having optical properties suitable for coupling into the projector.

In yet another aspect of the disclosure, a method for forming an emitter system assembly includes forming an emitter array on an emitter substrate, attaching the emitter substrate to a backplane, forming an array of cavities and apertures aligned with the emitter array, and attaching a lenslet array, aligned with the array of apertures.

In still another aspect of the disclosure, a low-n material with a lower index of refraction than the material forming the cavity is incorporated around at least a portion of the aperture.

In another aspect of the disclosure, one or more anti-reflective layers is incorporated into at least one of the cavities and the aperture.

In a further aspect of the disclosure, the emitter substrate incorporates conductive material arranged to serve as a cathode shared between two or more emitters.

In another aspect of the disclosure, the emitter system includes light containment features around the emitter. In an example, the light containment features include one or more reflective layers surrounding the emitter. In an aspect, the light containment features are formed of a structure including a metal layer or a reflective, dielectric stack.

### BRIEF DESCRIPTION OF THE DRAWINGS

The appended drawings illustrate only some implementation and are therefore not to be considered limiting of scope.

FIG. 1 illustrates an example of a display having multiple pixels, in accordance with aspects of this disclosure.

FIGS. 2 and 3 illustrate examples of a light field display having multiple picture elements, in accordance with aspects of this disclosure.

FIG. 4 illustrates a general configuration for light extraction from an LED, in accordance with aspects of this disclosure.

FIGS. 5-7 illustrate examples of light extraction configurations, in accordance with aspects of this disclosure.

FIGS. 8-10 illustrate examples of configurations for light extraction from an array of microLEDs, in accordance with aspects of this disclosure.

FIG. 11 shows a flow chart illustrating a process for forming light extraction configurations for microLEDs, in accordance with aspects of this disclosure.

FIGS. 12 and 13 illustrate further examples of light extraction configurations, in accordance with aspects of this disclosure.

FIGS. 14 and 15 illustrate a partial cross-sectional view and a partial top view of an emitter array with light extraction and shared cathode features, in accordance with aspects of this disclosure.

FIGS. 16-19 illustrate examples of light containment features for containing the light emitted by the emitter, in accordance with aspects of this disclosure.

FIGS. 20-26 illustrate an exemplary process flow for forming an emitter with structures for light extraction, in accordance with aspects of this disclosure.

FIGS. 27-37 illustrate possible variations for emitters and emitter arrays with light extraction configurations, in accordance with aspects of this disclosure.

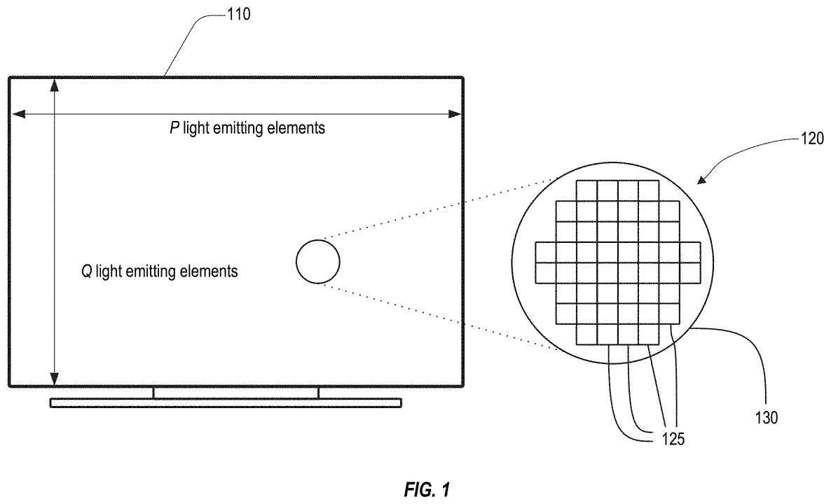

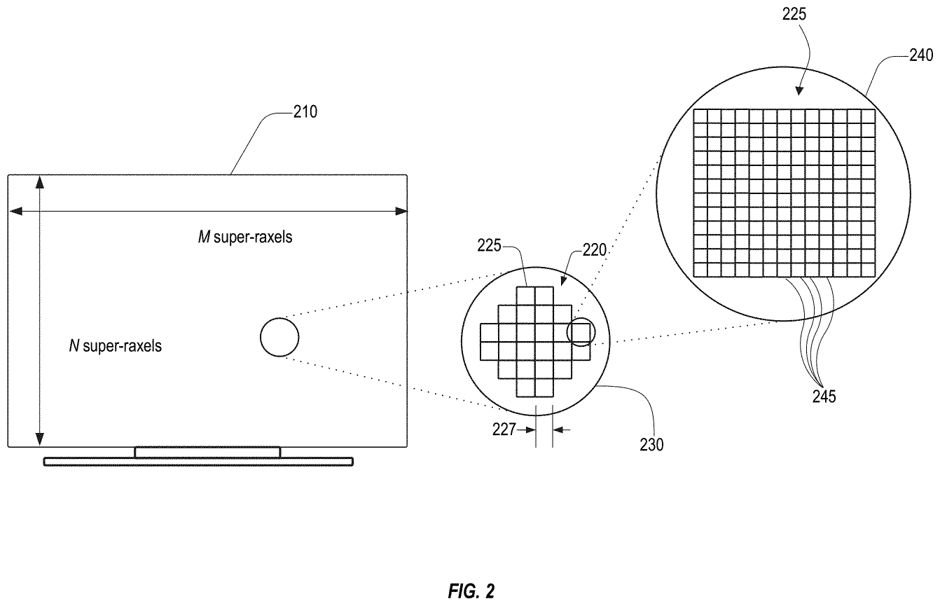

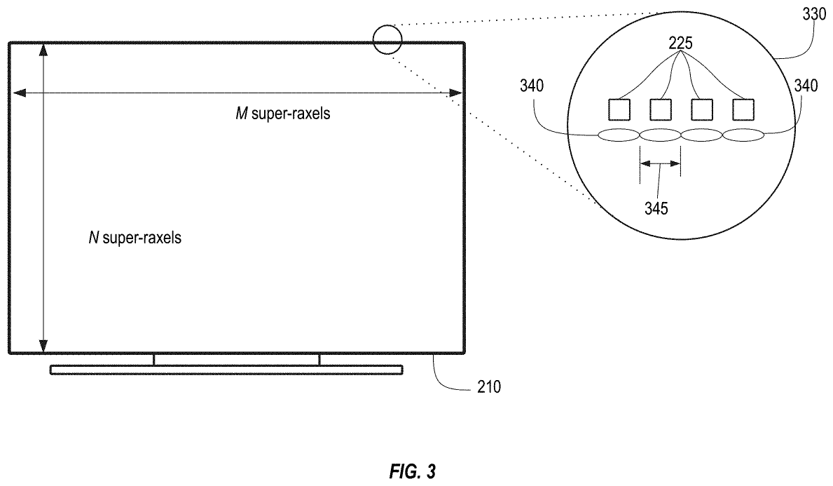

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known components are shown in block diagram form in order to avoid obscuring such concepts.

In order to effectively take advantage of the small size and high efficiency of microLEDs, as much of the light produced by each microLED should be extracted as possible. Accordingly, new configurations are desirable for improved extraction of light produced by microLEDs.

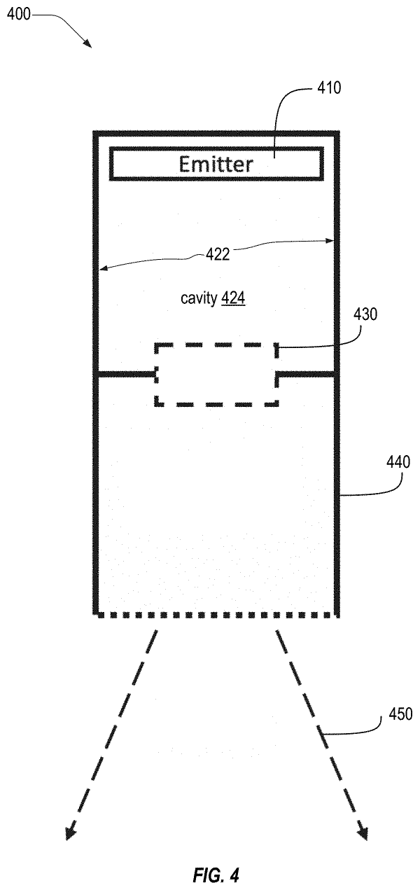

FIG. 4 shows an exemplary configuration for improved light extraction from a light emitter such as microLEDs. As shown in FIG. 4, an emitter system 400 includes an emitter 410 for generating light emission. For instance, emitter 410 may be a conventional LED or microLED based on quantum well (QW) technology, or another type of small light emitter. Emitter 410 is at least partially surrounded by surfaces 422, which define an LED cavity. Surfaces 422 may be a single continuous concave surface. In embodiments, surfaces 422 are surfaces of a substrate 420.

An etendue gate 430 provides a spatial aperture for light from emitter 410 to be released toward mode-matching optics 440. Mode-matching optics 440 is configured for shaping light from the LED cavity into an output 450 that matches the requirements of a specific application, such as for use in a projector device. It is noted that, while emitter 410 is shown as a solid block, it may include a plurality of layers, such as n-doped semiconductor layers, one or more quantum well structures, lattice matching layers, hole blocking layers, electron blocking layers, contact layers, and other materials known in the art of semiconductor emitter manufacturing.

More specifically, surfaces 422 may be high reflectivity surfaces for containing the light produced by emitter 410. The geometry of the LED cavity may be tailored for specific applications to provide an optimal geometry for optical coupling through etendue gate 430. It is noted that, although called a “cavity,” the LED cavity may be filled with a material other than air, such as a solid semiconductor (such as gallium nitride) or another material (such as an insulator) that is substantially transmissive to the light emitted by emitter 410.

Etendue gate 430 may be a fixed or adjustable spatial aperture for efficiently coupling light out of the LED cavity with mode-matching optics 440. Etendue gate 430 may further include, for example, a filter for selectively transmitting light with specific characteristics therethrough, such as light incident at etendue gate 430 within a specific range of incident angles, polarization state, wavelength, resonant cavity mode, and other optical characteristics. For instance, etendue gate 430 may include one or more non-reflective, low-reflective, or anti-reflective layer for enhancing display contrast in the presence of external light. As an example, an array of emitter systems 400 may be formed into a display, each emitter system producing light contributing to an image produced by the display. In such a display, when there is external light introduced into the display, each etendue gate 430 may reflect the external light so as to detract from the image produced by the display. Such undesirable effects may be reduced by incorporating one or more non-reflective, low-reflective, or anti-reflective layer at etendue gate 430 such that any external light reaching etendue gate 430 may be integrated into the LED cavity.

Mode-matching optics 440 may include one or more refractive, reflective, or diffractive optics arranged in an imaging or non-imaging configuration. Mode-matching optics 440 may be tailored for providing output 450 matching the acceptance light field of the specific application. For instance, when emitter system 400 is intended for providing light emission for use in a projector, such as for augmented reality (AR) or virtual reality (VR) headsets, then mode-matching optics 440 may be configured for converting light transmitted through etendue gate 430 into output 450 that optimally matches the acceptance criteria for the projector. Again, non-reflective, low-reflective, or anti-reflective layers may be incorporated into mode-matching optics 440 to reduce the effects of external light being introduced into emitter system 400.

Referring back to FIG. 4, it is noted that a range of variations are possible for emitter 410, LED cavity 424, etendue gate 430, and mode-matching optics 440. For instance, emitter 410 may include a single emitter (e.g., a single light emitting diode), a group of two or more emitters of the same color, or a group of two or more emitters of different colors. As an example, emitter 410 may include a combination of a red LED, a green LED, and a blue LED within a single LED cavity 424. Alternatively, emitter 410 may include a combination of two LEDs emitting the same color, such as two red LEDs. LED cavity 424 may include, for instance, one or more surfaces including a high reflectivity coating, such as a silver or aluminum reflector. The high reflectivity coating material may be selected for providing low angular dependence in the reflective properties such that light over a range of incidence angles would be efficiently reflected within LED cavity 424.

Furthermore, etendue gate 430 may include a single aperture, as shown in FIG. 4, or multiple apertures. Further, etendue gate 430 may incorporate optical components such as a wavelength-selective filter, a polarizer, a grating structure, and/or a refractive element. The polarizer may transmit light of a first polarization state while reflecting light of a second, orthogonal polarization state back into LED cavity 424. In this way, the reflected light may be re-circulated within LED cavity 424 such that a portion of the reflected, re-circulated light may be transformed into the first polarization to be transmitted through the polarizer and out of LED cavity 424.

In embodiments, the polarizer, or the reflective surfaces within LED cavity 424, may include features for randomizing the polarization state of light transmitted therethrough or reflected. Alternatively, multiple etendue gates 430 may be coupled with LED cavity 424. In embodiments, a first etendue gate include a polarizer for transmitting light of a first polarization state while a second etendue gate includes a polarizer for transmitting light of an orthogonal, second polarization state such that the first etendue gate directs light toward a first location, while the second etendue gate directs light toward a different, second location.

While FIG. 4 shows etendue gate 430 as being aligned with emitter 410, etendue gate 430 may alternatively be offset from a centerline (e.g., optical axis) of emitter 410 for tailoring the amount and directionality of light transmitted through etendue gate 430 to accommodate the requirements of mode-matching optics 440. Further, the distance of etendue gate 430 with respect to emitter 410 and mode-matching optics 440 may be adjusted according to the desired optical output.

Additionally, mode-matching optics 440 may include at least of the following types of optical components: refractive, filtering, polarizing, diffractive, and reflective. Mode-matching optics may form an imaging optical system or a non-imaging optical system. For instance, mode-matching optics 440 may include one or more of spherical, cylindrical, and asymmetric optical components. Mode-matching optics 440 may further include one or more gratings, filters, and/or polarizers. Mode-matching optics 440 may be tailored for the needs of specific uses, such as to provide light output with specific beam parameters, such as beam shape, telecentricity, and directionality, for optimizing the coupling of the light output with downstream optics, such as a projector and/or a waveguide.

For example, when red, green, and blue LEDs are included as emitter 410, etendue gate 430 and mode-matching optics 440 may be positioned with respect to the LEDs and exhibit wavelength-dependent refraction behaviors such that the red, green, and blue light produced by the LEDs may be directed toward different directions according to color. Additionally, one or more reflective surface may be incorporated around emitter 410, as a surface that at least partly defines cavity 424 for example, such that the emitted light from emitter 410 anywhere around emitter 410 may be contained and reflected into LED cavity 424. In this way, light distribution from emitter 410 may be optimized for coupling into, for example, an input coupling grating (ICG), which may exhibit incidence angle-dependent light coupling behavior.

The aperture shape of etendue gate 430 and/or mode-matching optics 440 may be circular, cylindrical, elliptical, rectangular, or square. Further, any of the surfaces of emitter 410, LED cavity 424, etendue gate 430, and mode-matching optics 440 may include one or more of a variety of features such as gratings, textures, anti-reflective coatings, low refractive index layers, light absorbing materials, insulating materials, conductive materials, semiconductor materials, and alloys.

In general, the position and shape of emitter 410, LED cavity 424, etendue gate 430, and mode-matching optics 440 may be decoupled from each other, thus providing flexibility in the design of the various components in position and shape and can be tailored emitter by emitter or pixel by pixel. The shape and design of each of the components shown in FIG. 4 may be formed, for example, by optical lithography, wet or dry etch procedures, nano-imprinting, and other known processing techniques. In this way, the shape and design of each of the components shown in FIG. 4 may be modified across an array of LED emitter systems 400. Further, one or more color converters or other components for wavelength-dependent filtering, color conversion, attenuation, color adjustment, phase modification, and/or wavefront shaping may be incorporated within one or more of emitter 410, LED cavity 424, etendue gate 430, and mode-matching optics 440.

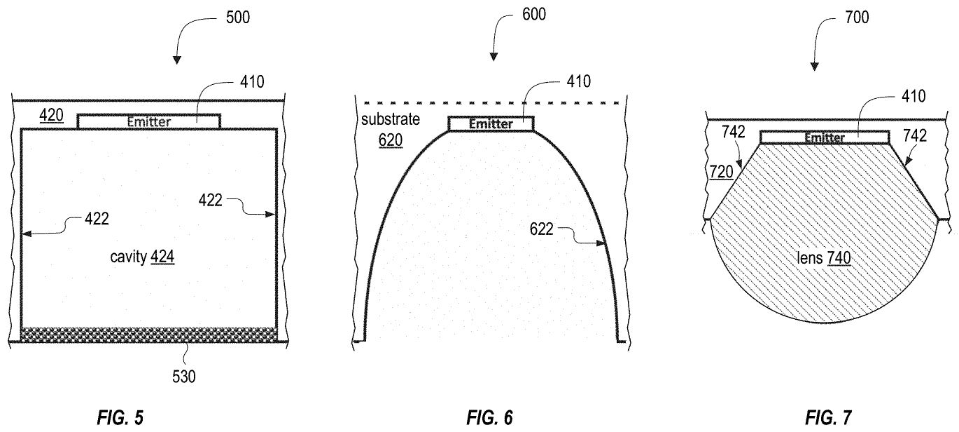

In an alternative embodiment, as shown in FIG. 5, etendue gate 430 and mode-matching optics 440 for an emitter system 500 may be replaced by a textured surface 530 for diffusing the light emitted from emitter 410. In this case, surfaces 422 of the LED cavity may be configured for efficiently directing light emitted from emitter 410 toward textured surface 530, to provide light output suitable for use in applications that do not require a collimated light output.

In certain cases, with the appropriate design for mode-matching optics 440, the LED cavity may be reduced or eliminated. For example, as shown in FIG. 6, an emitter system 600 may include emitter 410 positioned at the vertex or focal plane of a surface 622 that defines a truncated compound parabolic curve (CPC), where surface 622 serves as mode-matching optics 440. In the case of emitter system 600, surface 622 may provide sufficient mode-matching and shaped light output for certain applications. Surface 622 may be, or include, a concave paraboloidal surface. Surface 622 may be a reflective surface, such as one formed of metal or dielectric coating. Surface 622 may be a surface of a substrate 620.

Alternatively, as shown in FIG. 7, an aspherical lens 740 may be used as mode-matching optics 440 formed adjacent to emitter 410. Aspherical lens 740 may include shaped sidewalls 742 such that, with an appropriate design of shaped sidewalls 742, aspherical lens 740 alone, without a cavity, provides a suitably shaped light output for certain applications. In embodiments, sidewalls 742 are adjacent to surfaces of a substrate 720. Each of substrates 620 and 720 is an example of substrate 420.

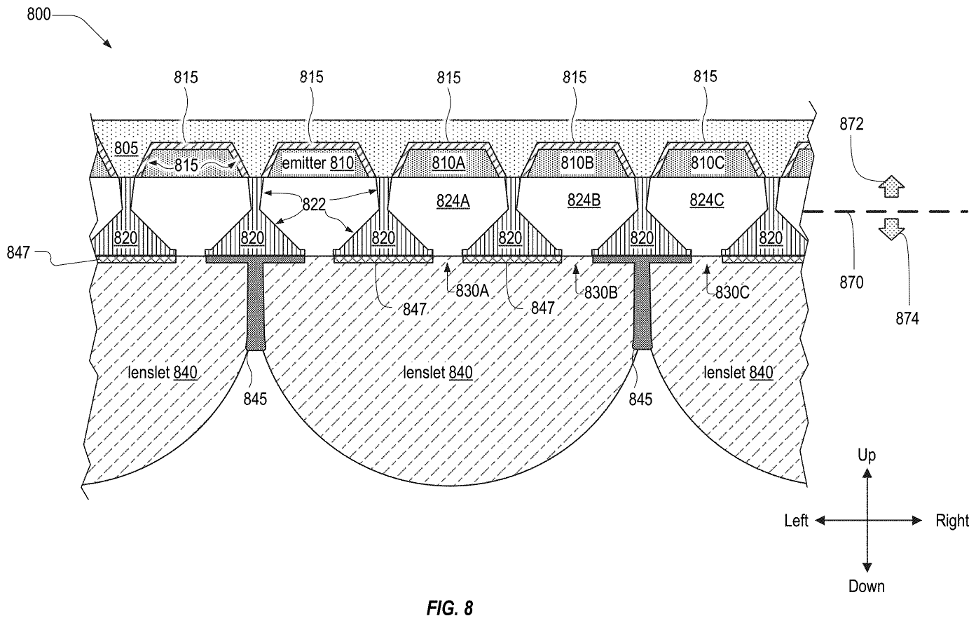

FIG. 8 shows a cross-sectional view of an emitter array system 800 including light extraction features, in accordance with an embodiment. Emitter array system 800 includes an LED substrate 805 that supports, and/or at least partially includes, a plurality of emitters 810. Emitters 810 may be arranged in a two-dimensional array. Each emitter 810 is an example of emitter 410, and is at least partially surrounded by a recessed surface of LED substrate 805.

Emitters 810 include at least one of each of emitters 810A, 810B, and 810C. In embodiments, emitters 810A, 810B, and 810C are configured to emit light in a different respective one of three wavelength ranges. In embodiments, the ranges correspond to the red, green, and blue regions of the electromagnetic spectrum. In another configuration, emitters 810A, 810B, and/or 810C may be configured to emit light in the same wavelength range.

In an example, each one of emitters 810A, 810B, and 810C is surrounded by reflective surfaces 815 such that light emitted by that emitter is directed downward in FIG. 8. Reflective surfaces 815 may be a coating formed of a metal (e.g., aluminum, gold, silver), a dielectric, a multi-layer film stack of dielectric materials, or any combination thereof. When reflective surface 815 is a coating, the coating may be on a recessed surface of LED substrate 805.

Emitter array system 800 further includes a substrate 820 that has cavities defined by surfaces 822. Substrate 820 may be part of substrate 805. Examples of surface 822 include surface 422 and surface 622. Example of substrate 820 include substrates 420, 620, and 720.

Each respective LED cavity 824A, 824B, and 824C, are adjacent to emitters 810A, 810B, and 810C, respectively. Substrate 820 may be formed of a semiconductor (such as GaN) or other material (such as an insulator or a transparent conductive oxide) compatible with light transmission in the desired wavelengths. Reflective surfaces 822 may have a coating thereon, which may be formed of a metal (e.g., aluminum, gold, silver), a dielectric, a multi-layer film stack of dielectric materials, or any combination thereof.

Reflective surfaces 822 contain and/or shape light emitted from emitters 810A, 810B, and 810C, respectively. In embodiments, each surface 822 extends between an upper surface and a lower surface of substrate 820 such that surface 822 defines an aperture through substrate 820. For example, LED cavity 824A may be defined by a cavity geometry optimized for coupling light emitted by emitter 810A to an aperture 830A, LED cavity 824B may be optimized for coupling light emitted by emitter 810B to an aperture 830B, and LED cavity 824C may be formed to be best compatible with light emitted by emitter 810C to be coupled to an aperture 830C. In another example, two or more of LED cavities 824A, 824B, and 824C may be identical to each other. Similarly, apertures 830A may be distinct from apertures 830B and/or 830C, or apertures 830A, 830B, and 830C may be identical in dimensions.

Apertures 830A, 830B, and 830C may be formed conjugate with the plane of an input coupling grating (ICG), such as those serving as an input port of a waveguide for near-eye display glasses. Other types of throughput-limiting aperture configurations may be implemented according to the requirements of the mode coupling optics or other downstream optics from the apertures. Further, optionally, at least one of apertures 830A, 830B, and 830C may include additional optical properties, such as angular, wavelength, and/or polarization filtering capabilities.

Light emanating from LED cavities 824A, 824B, and 824C through apertures 830A, 830B, and 830C, respectively, is directed through lenslets 840 in the example illustrated in FIG. 8. Each one of lenslets 840 is an example of mode-matching optics 440 of FIG. 4. In the example shown in FIG. 8, each lenslet 840 is configured for directing light from multiple emitters 810A, 810B, and 810C. Each one of lenslets 840 may be formed, for example, directly on the backplane, or be part of a lenslet array formed separately then attached to the backplane after formation of the apertures and absorber coatings.

Emitter array system 800 may include baffle absorbers 845, which separate adjacent lenslets 840. For instance, light baffle absorbers 845 may be configured for reducing crosstalk between adjacent lenslets 840. Additionally, areas between apertures 830A, 830B, and 830C may be covered by an absorbing layer 847 for further reducing stray light traveling through lenslets 840.

In embodiments, a line 870 represents a demarcation, above which the formation of emitters 810A, 810B, and 810C, reflective surfaces 815, part of LED cavities 824A, 824B, and 824C, and reflective surface 822 may be formed as part of the microLED fabrication (as indicated by an arrow 872). Below line 870 (as indicated by an arrow 874), the various components may be formed during processing performed after microLED fabrication has been completed.

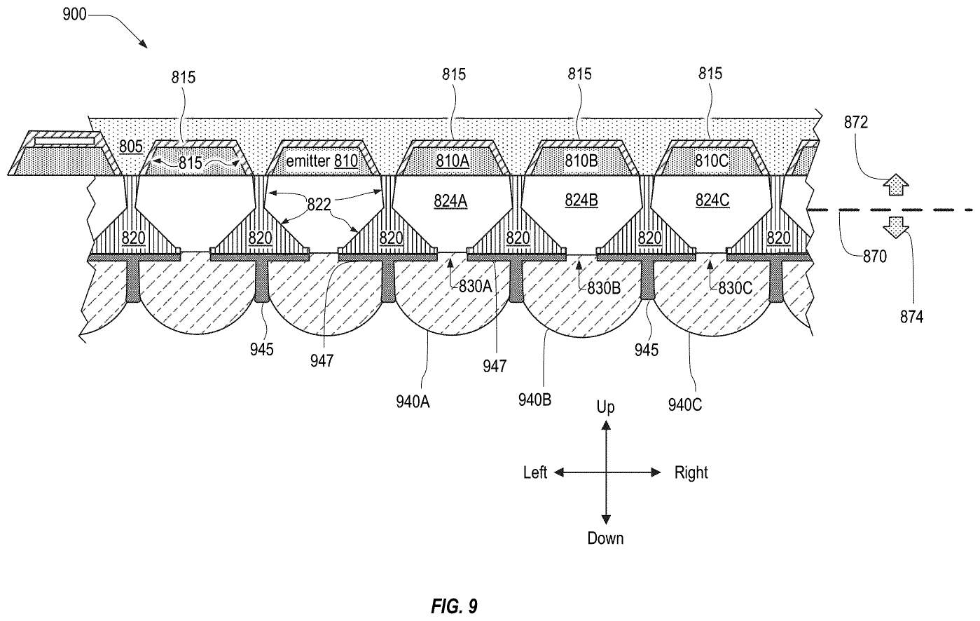

FIG. 9 shows an emitter array system 900, in accordance with an embodiment. Emitter array system 900 includes the same microLED fabrication side components as emitter array system 800 of FIG. 8. However, each one of apertures 830A, 830B, and 830C is coupled with its own lenslet 940A, 940B, and 940C, respectively. Adjacent lenslets 940A, 940B, and 940C are separated by light baffle absorbers 945, and areas between apertures 830A, 830B, and 830C may be covered by an absorber layer 947. In this configuration, each one of lenslets 940A, 940B, and 940C may be configured for coupling with the specific wavelength and other light characteristics of the light emitted by the corresponding one of emitters 810A, 810B, and 810C.

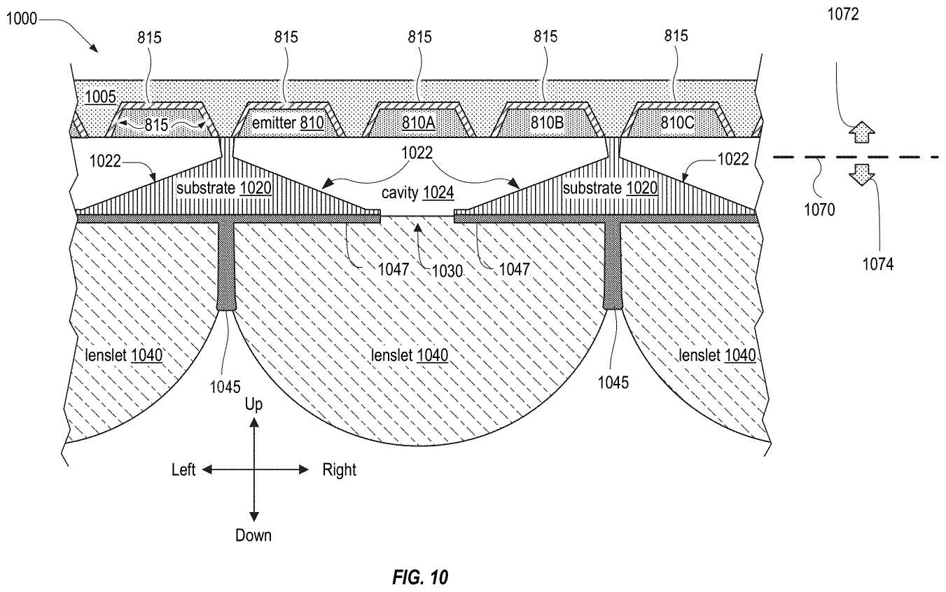

FIG. 10 shows an emitter array system 1000, in accordance with an embodiment. Emitter array system 1000 includes an LED substrate 1005 supporting emitters 810A, 810B, and 810C with reflective surfaces 815, as illustrated in FIG. 8. In contrast to emitter array system 800 of FIG. 8, emitter array system 1000 includes one LED cavity 1024 for a group of emitters 810A, 810B, and 810C. Emitter array system 1000 further includes a substrate 1020 that has surfaces 1022, which define cavities 1024. Substrate 1020 may be part of substrate 1005. The geometry of LED cavity 1024 and the properties of substrate 1020 may be tailored for optimum coupling of light emitted from emitters 810A, 810B, and 810C to an aperture 1030 and into a lenslet 1040. Lenslet 1040 is an example of lenslet 840 of FIG. 8. Adjacent lenslets 1040 may be separated by light baffle absorbers 1045, and areas between apertures 1030 may be coated with an absorber material 1047. Substrates 1005 and 1020 are examples of substrates 805 and 820, respectively.

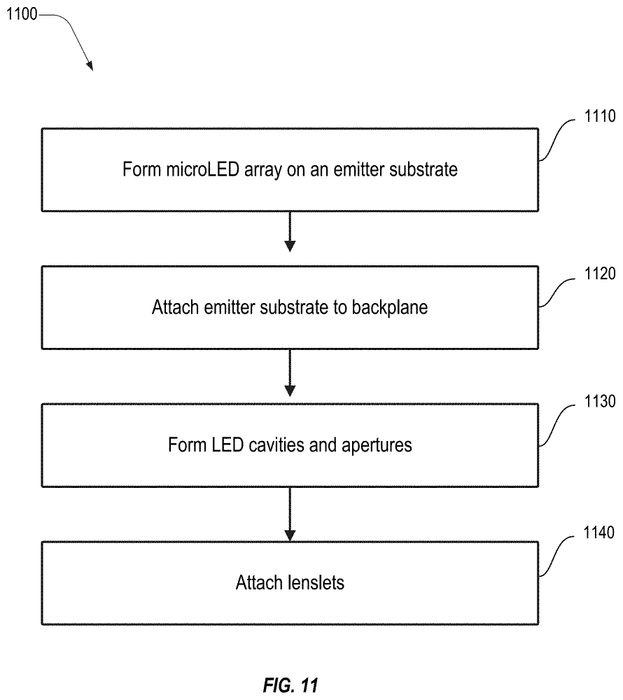

FIG. 11 shows an exemplary process 1100 for forming the emitter array systems disclosed above, in according to an embodiment. Process 1100 includes a step 1110 of forming an emitter array on an emitter substrate. In reference to FIG. 8, forming emitters 810A, 810B, and 810C supported on or within substrate 805, step 1110 may also include at least one of (i) forming reflective surfaces 815 surrounding emitters 810A, 810B, and 810C, (ii) forming the microLED-side of LED cavities 824A, 824B, and 824C, and (iii) forming portions of reflective surfaces 822.

Process 1100 proceeds to a step 1120 to attach the emitter array to a backplane, then a step 1130 to form the rest of the LED cavities and apertures. For instance, the emitter array may be attached to the backplane, after which the emitter substrate, supporting the emitter array, may be removed. Finally, process 1100 proceeds to a step 1140 to attach the lenslets to form the structures illustrated, for example, in FIGS. 8-10.

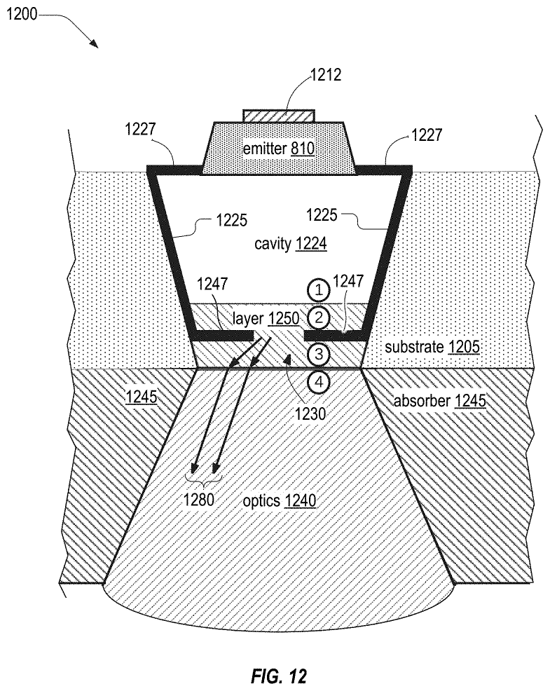

Additional examples of embodiments of light extraction configurations are illustrated in FIGS. 12-37.

FIG. 12 shows an emitter system 1200 including an emitter 810 with an ohmic contact 1212. Light emitted from emitter 810 is directed into an LED cavity 1224. Emitter system includes a substrate 1205, which is an example of substrate 805. Substrate 1205 includes a sidewall 1225. Cavity 1224 is defined by respective surfaces of sidewall 1225, a baffle 1247, a top reflector 1227. One or both of baffle 1247 and reflector 1227 may be part of substrate 1205. Sidewall 1225 may include one more sidewalls, and may be a layer deposited on substrate 1205.

A portion of the light from LED cavity 1224 is transmitted through an etendue gate 1230 and through mode-matching optics 1240 (shown here as a refractive element). Etendue gate 1230 and optics 1240 are respective examples of an etendue gate 430 and optics 440. The optical properties of mode-matching optics 1240 (e.g., shape, refractivity, beam shaping/steering) are tailored to optimize coupling of light from emitter 810 with downstream optical systems, such as a projector or a waveguide. Sidewall 1225 contain light emitted from emitter 810 within LED cavity 1224. In embodiments, top reflector 1227 covers gaps around emitter 810 and reflective sidewall 1225 to prevent light from escaping through the gaps. Top reflector 1227 may be used as an electrical contact.

Continuing to refer to FIG. 12, absorber 1245 surrounds mode-matching optics 1240 to absorb any stray light not directed out of mode-matching optics 1240. Further, baffle 1247, which serves to define the boundaries of etendue gate 1230, may also exhibit light absorption properties to reduce stray light from re-entering LED cavity 1224 from mode-matching optics 1240.

As shown in FIG. 12, a low-index (low-n) layer 1250 surrounds etendue gate 1230 and baffle 1247. The refractive index of low-n layer 1250 may be a value lower than the material filling LED cavity 1224. As an example, when LED cavity 1224 is filled with an n-doped gallium nitride (n-GaN) with an average refractive index of n=2.4, then low-n layer 1250 may be a material with an average refractive index lower than 2.4. Examples include materials with an average index of refraction of n=1.4, such as a polymer. Similarly, mode-matching optics 1240 may be formed of a higher index polymer, such as those exhibiting n=1.7, such that there is a refractive index discontinuity between low-n layer 1250 and mode-matching optics 1240.

Consequently, there are multiple interfaces encountered by light emitted from emitter 810, as indicated by numbers enclosed in circles in FIG. 12. At the (1)-(2) interface, light from LED cavity 1224 encountering low-n layer 1250 is mostly reflected back into LED cavity 1224 due to the refractive index discontinuity at the interface. Similarly, at the (3)-(4) interface, light is refracted as indicated by arrows 1280. Finally, as light exits mode-matching optics 1240, the light is shaped and directed toward external optical systems. Thus, the inclusion of low-n layer 1250 helps to further tailor the light containment and efficient extraction of light emitted by emitter 810.

While a single emitter system 1200 is shown in FIG. 12, a plurality of emitter systems 1200 may be arranged in an array. The emitter systems within the array may be identical, or emitter systems with different light emission characteristics may be included within the array.

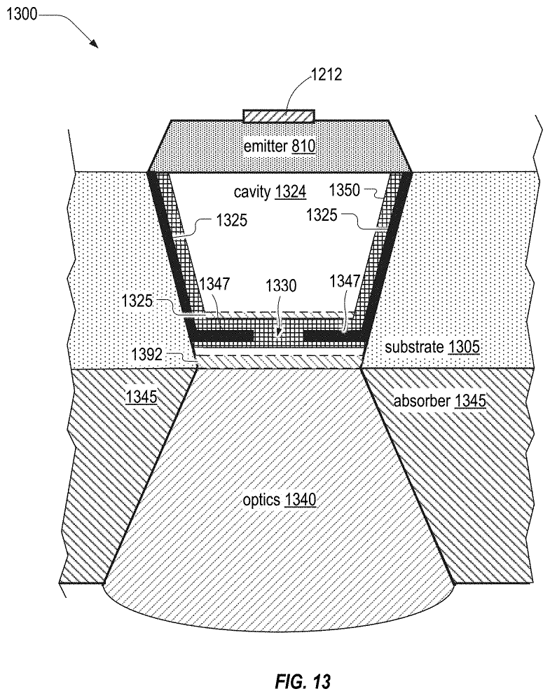

FIG. 13 illustrates another example of a light extraction configuration, in accordance with aspects of this disclosure. As shown in FIG. 13, an emitter system 1300 includes a light emitter 810 with an ohmic contact 1212. Light emitted from emitter 810 is directed into an LED cavity 1324. Emitter system 1300 includes a substrate 1305, which is an example of substrate 805. Substrate 1305 includes a sidewall 1325. Cavity 1324 is defined at least in part by respective surfaces of sidewall 1325 and a baffle 1347. Baffle 1347 may be part of substrate 1305. Sidewall 1325 may include one more sidewall, and may be a layer deposited on substrate 1305.

A portion of light from LED cavity 1324 is transmitted through an etendue gate 1330 and through mode-matching optics 1340. Etendue gate 1330 is an example of an etendue gate 430. Again, the optical properties of mode-matching optics 1340 are tailored to optimize coupling of light from emitter 810 with downstream optical systems, such as a projector or a waveguide. Reflective sidewalls 1325 containing light emitted from emitter 810 within LED cavity 1324. Absorbers 1345 surround mode-matching optics 1340 to absorb any stray light not directed out of mode-matching optics 1340. Further, baffle 1347, which serve to define the boundaries of etendue gate 1330, may also exhibit light absorption properties to reduce stray light from re-entering LED cavity 1324 from mode-matching optics 1340. In embodiments, etendue gate is an aperture through baffle 1347.

Emitter system 1300 incudes a low-n layer 1350, which is similar to low-index layer 1250 of emitter system 1200. Parts low-n layer are above and below baffle 1347, and in etendue gate 1330. Low-n layer 1350 also extends along reflective sidewalls 1325 to further enhance the light containment properties of LED cavity 1324. Additionally, emitter system 1300 may include an anti-reflective layer 1390 at the interface between the high index material forming LED cavity 1324 and low-n layer 1350.

In embodiments, emitter system 1300 includes a second anti-reflective layer 1392 at the interface between low-n layer 1350 and mode-matching optics 1340. Moreover, a third anti-reflective layer (not shown) may be included at the interface between mode-matching optics 1340 and any downstream optics (not shown). The anti-reflective layers may serve to enhance the coupling of light emitted from emitter 810 out of LED cavity 1324 and into mode-matching optics 1340.

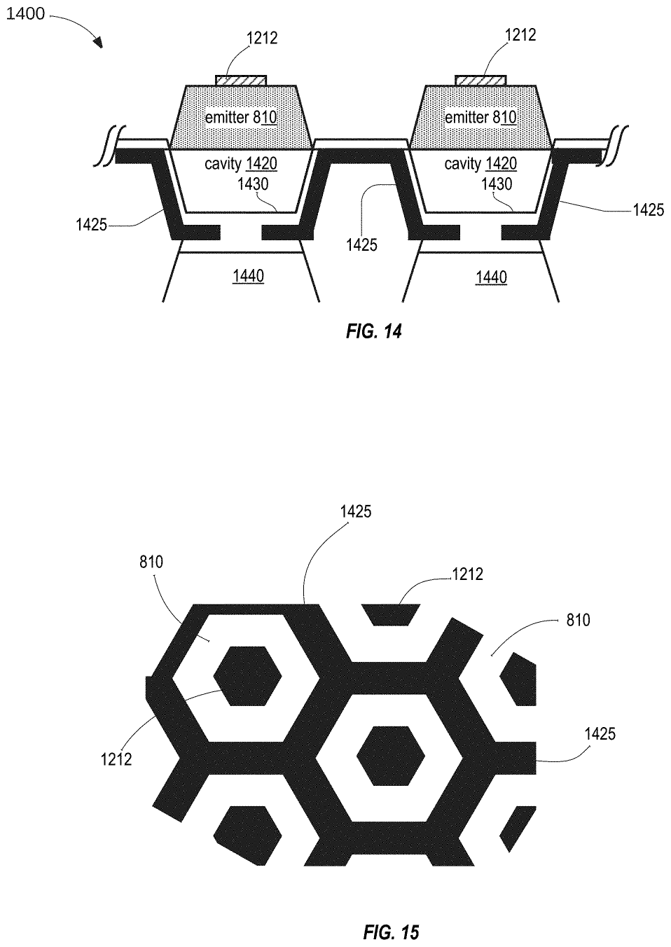

FIGS. 14 and 15 respectively illustrate a partial cross-sectional view and a partial top view of an emitter system 1400 with light extraction and shared cathode features, in accordance with aspects of this disclosure. By expanding the reflective, light containment layer around the LED cavities and between the emitter systems, the reflective layers themselves may be used as a shared cathode for electronically addressing the light emitters. In particular, an emitter system 1400 includes multiple emitters 810, each emitter individually addressable via an ohmic contact 1212. Like previously describe emitter systems, each emitter 810 is coupled with an LED cavity 1420 surrounded by a reflective layer 1425. Reflective layer 1425 is an example of sidewalls 1225 and 1325, and may be formed, for example, of a reflective metal material. Light from emitter 810 is coupled via LED cavity 1420 into mode-coupling optics 1440. Mode-coupling optics 1440 may be an example of mode-matching optics 440. Emitter system 1400 may include a substrate, such as substrate 1205 or 1305, in which case reflective layer 1425 may be a layer deposited on the substrate.

In embodiments, low-n layers 1430 may be incorporated into LED cavity 1420, mode-coupling optics 1440, or anywhere in between to aid in increasing the efficiency of light containment within LED cavity 1420 and out of mode-coupling optics 1440. Low-n layer 1450 may also extend between emitters 810 to serve as an insulating layer for electronically isolating emitters 810 from each other.

As shown in FIGS. 14 and 15, reflective layer 1425 may extend between emitters 810 such that reflective layer 1425 may be used as a shared cathode for the emitters 810 within emitter system 1400. Individual addressing of each emitter 810 may be accomplished via bonding through its associated ohmic contact 1212.

It should be noted that, when silver is incorporated into the reflective layers described above (e.g., reflective surfaces 1225, 1325, 1425), a known problem is the migration of silver into undesired areas of the emitter system, which can lead to electrical shorting of the emitters. A configuration of low-n layers 1350 and 1430 of FIGS. 13 and 14 may help mitigate the migration of silver into the LED cavities. Further, reflective surfaces 1225, 1325, and 1425 described above may additionally be encapsulated in a coating, thus retaining the reflective properties of the reflectors while mitigating problems related to electric-field induced silver migration.

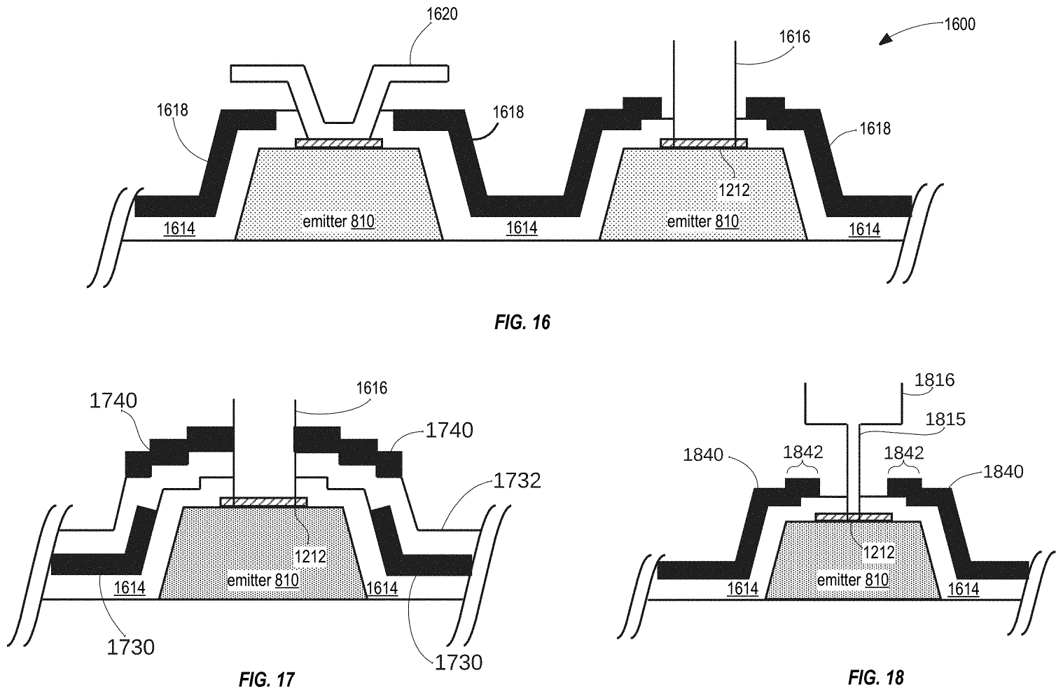

FIGS. 16-19 illustrate examples of light containment features for containing the light emitted by the emitter, in accordance with aspects of this disclosure. It is noted that FIGS. 16-19 show only the structures surrounding the emitter portion of the emitter systems; that is, the embodiments illustrated in FIGS. 16-19 may further incorporate light extraction structures, as illustrated in FIGS. 4-15 described above.

Referring first to FIG. 16, the figure shows a portion of an emitter array 1600 incorporating light containing mechanisms is illustrated. Emitter array 1600 includes a plurality of emitters 810, each topped with an ohmic contact 1212. In large part, light emitted from emitters 810 can be directed downward (i.e., toward the bottom of the page). However, a small portion of the light emission does escape around each emitter 810. While ohmic contact 1212 blocks most of the light emission directed upward (i.e., toward the top of the page), light emission may escape from the sides of emitters 810.

To address the upward and sideways light leakage, each emitter 810 may be surrounded by a reflective material to direct the light leakage downward, such as toward a light extraction structure described above with respect to FIGS. 4-15. In the example illustrated in FIG. 16, emitters 810 are covered by a passivation or isolation layer 1614. Using known techniques, such as dry etch, wet etch, and mask lithography, reflective structures 1618 are deposited on the sides and upward toward the ohmic contacts of each emitter 810. Passivation layer 1614 isolates reflective structures 1618 from contacting emitters 810 and ohmic contacts 1612. An additional passivation or isolation layer may be deposited on top of reflective structures 1618, then an additional “wing” structure 1620 may be formed in order to further provide containment of light escaping around ohmic contacts 1612. An electrical contact may then be made directly with ohmic contact 1212, as shown in the emitter structure on the right of FIG. 16 (shown as electrical contact 1616), or via wing structure 1620, as shown in the emitter structure on the left. Embodiments of any one of emitter systems described in FIGS. 8-15 may include at least one of isolation layer 1614, reflective structures 1618, electrical contact 1616, and wing structure 1620.

Even if a direct contact is made to ohmic contact 1212, FIG. 17 shows an alternative embodiment in which a wing structure is formed in direct electrical contact with the ohmic contact. For example, after passivation layer 1614 has been deposited over emitter 810 and ohmic contact 1212, reflective structures 1730 may be formed on the sides of emitter 810. An additional passivation layer 1732 is deposited over reflective structures 1730. Then, an additional reflective structure 1740 is deposited thereon, as shown in FIG. 17.

Subsequently, access through passivation layer 1614, additional passivation layer 1732, and additional reflective structure 1740 may be made to ohmic contact 1212, such that electrical contact 1616 may be connected with ohmic contact 1212 while preserving electrical isolation between adjacent emitters 810. Embodiments of any one of emitter systems described in FIGS. 8-16 may include at least one of reflective structures 1730, passivation layer 1732, and reflective structure 1740.

FIG. 18 shows an alternative configuration where a thin contact is used to electrically address ohmic contact 1212. As shown in FIG. 18, passivation layer 1614 covers emitter 810 and ohmic contact 1212, and a large reflective structure 1840 is deposited thereon such that there is an overlap 1842 between ohmic contact 1212 and large reflective structure 1840 while maintaining space between large reflective structures 1840 to enable electrical access to ohmic contact 1212 using a thin bonding wire 1815 attached to a thicker bonding wire 1816. In this way, light containment around emitter 810 may be established with one pass of reflective layer deposition without creating a short between the emitter, large reflective layer, and thin bonding wire 1815. Embodiments of any one of emitter systems described in FIGS. 8-16 may include at least one of reflective structures 1830, overlap 1842, thin bonding wire 815, and thicker bonding wire 1816.

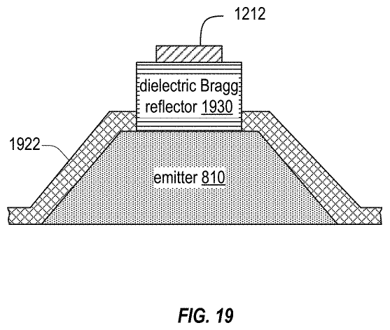

Still another alternative structure for light containment is shown in FIG. 19, which illustrates a portion of an array of emitter systems. As shown in FIG. 19, an emitter system 1900 includes at least one emitter 810. A passivation layer 1922 is formed over emitter 810 to provide electrical isolation. Optionally, a reflective structure (not shown) similar to those illustrated in FIGS. 16-18 may be formed on top of passivation layer 1922. Emitter system 1900 includes a dielectric Bragg reflector 1930 on emitter 810 to provide a reflective surface to contain light leakage from emitter 810.

Dielectric Bragg reflector 1930 includes multiple layers of dielectric thin films exhibiting alternating high and low refractive indices. In embodiments, and as shown in FIG. 19, dielectric Bragg reflector 1930 is in direct contact with emitter 810 through an aperture in passivation layer 1922. In embodiments, passivation layer 1922 may be incorporated into the design of dielectric Bragg reflector 1930 such that the refractive index of passivation layer 1922 contributes toward the overall reflectivity of Bragg reflector 1930, and the aperture in passivation layer 1922 is not required. Finally, an ohmic contact 1212 may be disposed on top of dielectric Bragg reflector 1930 for electronically addressing emitter 810.

Embodiments of any one of emitter systems described in FIGS. 8-16 may include at least one of passivation layer 1922, dielectric Bragg reflector 1930, and ohmic contact 1212 thereon.

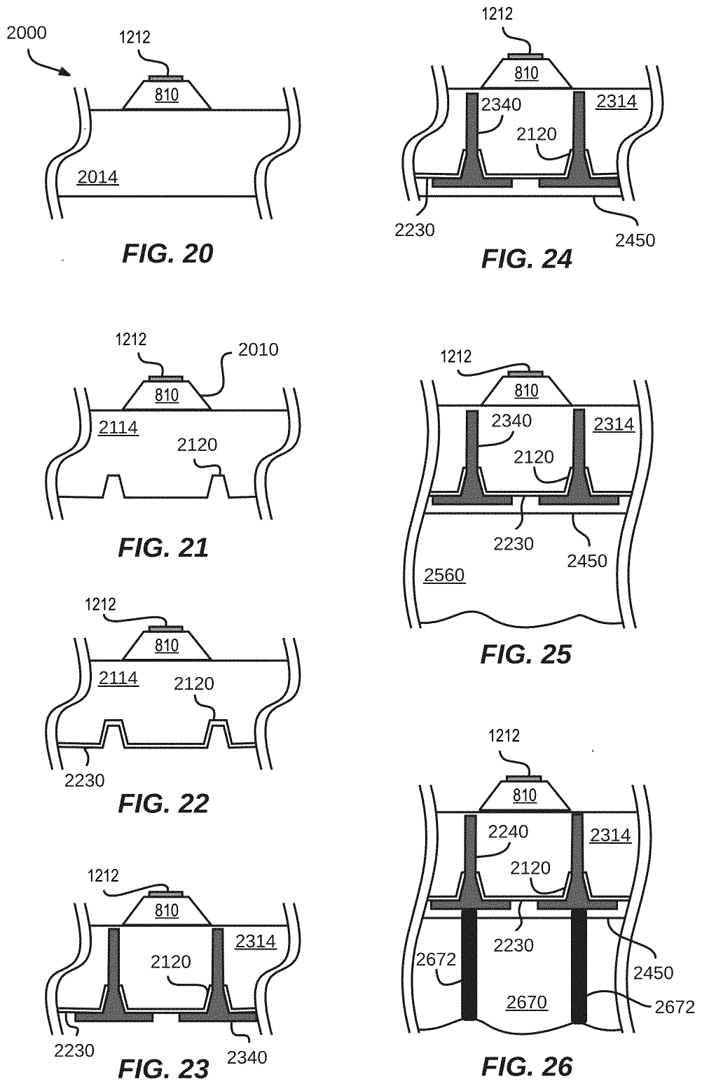

FIGS. 20-26 illustrate an exemplary process flow for forming an emitter with structures for light extraction, in accordance with aspects of this disclosure. As shown in FIG. 20, an emitter array structure 2000 includes an emitter 810 being formed on a planar surface of a semiconductor substrate 2014. An ohmic contact 1212 is on emitter 810. Semiconductor substrate 2014 is an example of substrate 805. In FIG. 21, semiconductor substrate 2014 has been modified to yield a semiconductor substrate 2114, which includes notches 2120 formed on the underside of the semiconductor substrate. In FIG. 22, a low-n layer 2230 (as an example, n<2.4) has been conformally deposited on the underside of semiconductor substrate 2114.

In FIG. 23, vias have been formed through notches 2120 and low-n layer 2230 into semiconductor substrate 2114 to yield a semiconductor substrate 2314. Further, reflective material 2340 has been deposited into the vias to form the basis of an LED cavity as discussed above.

In FIG. 24, another second layer of low-n material 2450 is deposited on the underside of semiconductor substrate 2314. In FIG. 25, a polymer material 2560 has been deposited to form the basis of mode-matching optics as discussed above. In FIG. 26, vias have been formed into polymer material 2560 and absorptive structures formed therein to form the mode-matching optics as discussed above.

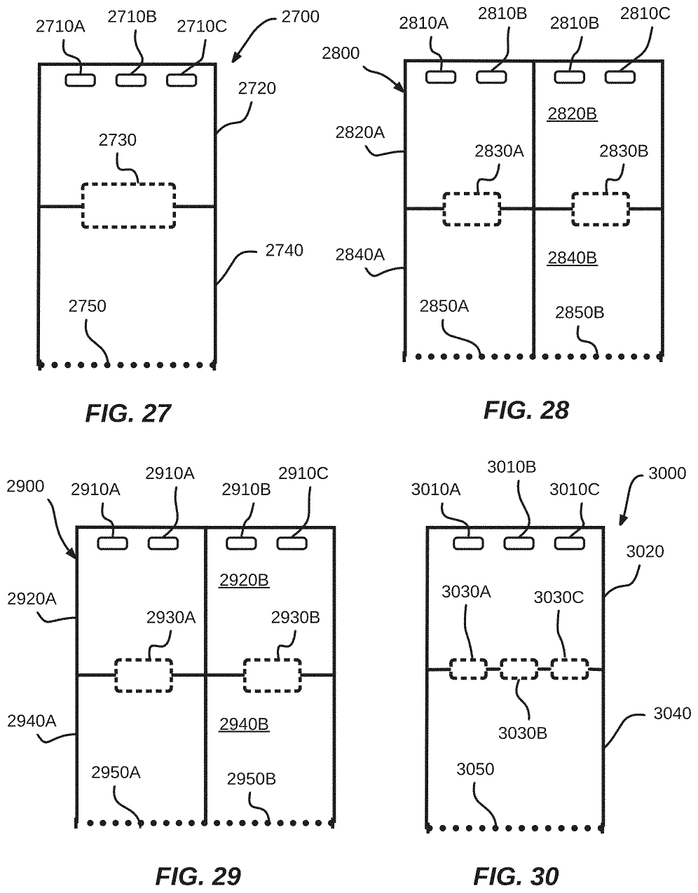

FIGS. 27-37 illustrate examples of possible variations for emitters and emitter arrays with light extraction configurations, in accordance with aspects of this disclosure.

FIG. 27 shows a variation of emitter system 400 of FIG. 4. As shown in FIG. 27, an emitter system 2700 includes three different emitters 2710A, 2710B, and 2710C, each emitting light at a distinct wavelength (e.g., emitter 2710A emitting in the red wavelength range, emitter 2710B emitting in the green wavelength range, and emitter 2710C emitting in the blue wavelength range) and disposed within a single LED cavity 2720. A single etendue gate 2730 connects LED cavity 2720 with mode-matching optics 2740 with an exit pupil 2750. This embodiment would correspond, for example, to one RGB pixel being incorporated into one light extraction structure.

As another example, FIG. 28 shows pairs of emitters located within each light extraction structure. As shown in FIG. 28, an emitter system 2800 includes a first emitter 2810A and a second emitter 2810B contained within a first LED cavity 2820A, connected with a first etendue gate 2830A, mode matching optics 2840A, and an exit pupil 2850A. Emitter system 2800 further includes another second emitter 2810B and a third emitter 2810C contained within a second LED cavity 2820B, connected with a second etendue gate 2830B, second mode matching optics 2840B, and a second exit pupil 2850B. As an example, the design of first etendue gate 2830A, mode matching optics 2840A, and exit pupil 2850A may be selected for optimal light containment and extraction for the specific combination of wavelengths emitted by first emitter 2810A and second emitter 2810B, while second etendue gate 2830B, second mode matching optics 2840B, and second exit pupil 2850B are optimized for the wavelengths produced by the combination of second emitter 2810B and third emitter 2810C.

Similarly, FIG. 29 shows an emitter system 2900 including a pair of first emitters 2910A contained with a first LED cavity 2920A, connected with a first etendue gate 2930A, mode matching optics 2940A, and an exit pupil 2950A. Emitter system 2900 further includes a second emitter 2910B and a third emitter 2910C contained within a second LED cavity 2920B, connected with a second etendue gate 2930B, second mode matching optics 2940B, and a second exit pupil 2950B. Such a configuration may be useful, for instance, in situations where the light emission efficiency of first emitter 2910A is significantly lower than those of emitters 2910B and 2910C such that optimization of light extraction efficiency for the pair of first emitters 2910A is necessary to create the desired light gamut from the combination of the three different emitters.

Alternatively, FIG. 30 shows a variation of emitter system 2700 of FIG. 27, this time including three different etendue gates. As shown in FIG. 30, an emitter system 3000 includes three different emitters 3010A, 3010B, and 3010C, each emitting light at a distinct wavelength (e.g., emitter 3010A emitting in the red wavelength range, emitter 3010B emitting in the green wavelength range, and emitter 3010C emitting in the blue wavelength range) and disposed within a single LED cavity 3020. Three separate etendue gates 3030A, 3030B, and 3030C connect LED cavity 3020 with mode-matching optics 3040 with an exit pupil 3050. This design may be effective, for instance, when it is desired to separate the directionality of light emission from each of emitters 3010A, 3010B, and 3010C at exit pupil 3050 by spatially filtering the light emission allowed through the three etendue gates. As an example, etendue gate 3030A may be optimized for allowing light of wavelengths emitted by emitter 3010A, etendue gate 3030B may be optimized for allowing light of wavelengths emitted by emitter 3010B, and etendue gate 3030C may be optimized for allowing light of wavelengths emitted by emitter 3010C, such that the direction of light rays transmitted through the three etendue gates are of specific wavelengths and directed generally in a known direction (e.g., directly downward in the figure).

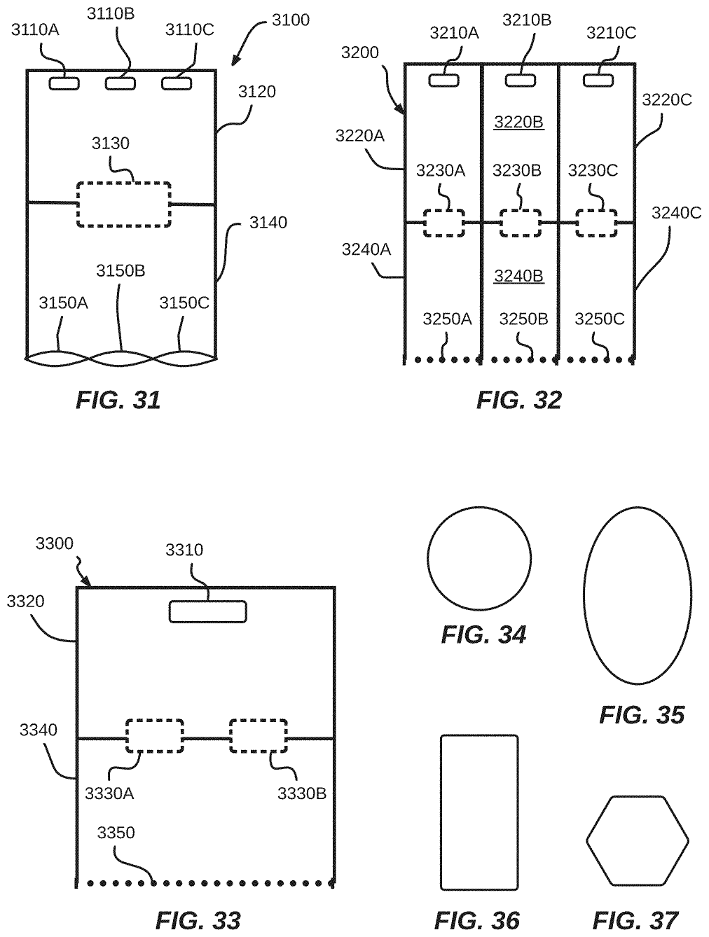

FIG. 31 shows another variation, including three different emitters, a single LED cavity, a single etendue gate, and three different output pupils. As shown in FIG. 31, an emitter system 3100 includes three different emitters 3110A, 3110B, and 3110C, each emitting light at a distinct wavelength (e.g., emitter 3110A emitting in the red wavelength range, emitter 3110B emitting in the green wavelength range, and emitter 3110C emitting in the blue wavelength range) and disposed within a single LED cavity 3120. Light emitted by emitters 3110 are transmitted through a single etendue gate 3130 into a single set of mode-matching optics, then directed toward three different output pupils 3150A, 3150B, and 3150C.

In contrast, FIG. 32 shows essentially a combination of three emitter systems 400, each being optimized for a specific light emission wavelength. As shown in FIG. 32, an emitter system 3200 includes a first emitter 3210A within a first LED cavity 3220A, connected with a first etendue gate 3230A, first mode-matching optics 3240A, and first exit pupil 3250A. Each of first LED cavity 3220A, first etendue gate 3230A, first mode-matching optics 3240A, and first exit pupil 3250A is optimized for light containment and extraction for the red wavelength range. Similarly, emitter system 3200 further includes a second emitter 3210B within a second LED cavity 3220B, connected with a second etendue gate 3230B, second mode-matching optics 3240B, and second exit pupil 3250B. Further, emitter system 3200 includes a third emitter 3210C within a third LED cavity 3220C, connected with a third etendue gate 3230C, third mode-matching optics 3240C, and a third exit pupil 3250C. Second LED cavity 3220B, second etendue gate 3230B, second mode-matching optics 3240B, and second exit pupil 3250B are optimized for working with green wavelengths, while third LED cavity 3220C, third etendue gate 3230C, third mode-matching optics 3240C, and third exit pupil 3250C are optimized for containing and directing blue wavelengths.

Still another variation is shown in FIG. 33. FIG. 33 shows an emitter system 3300 including an emitter 3310 contained within an LED cavity 3320. Each of emitters 2710, 2810, 2910, 3010, 3110, 3210, and 3310 is an example of emitter 810.

A first etendue gate 3330A and a second etendue gate 3330B may be configured for transmitting different portions of the light emitted by emitter 3310 (e.g., orthogonal polarization states, or low- and high-pass filtering) such that light transmitted through the first and second etendue gates exhibit different properties. The transmitted light is then directed through mode-matching optics 3340 and exit pupil 3350.

For the various etendue gates and exit pupils shown in FIGS. 8-10,12, 13, and 27-37 illustrate a few of the different possible shapes for the apertures presented by these components. For instance, as shown in FIG. 34, each etendue gate or exit pupil may be circular. Alternatively, as shown in FIG. 35, each etendue gate or exit pupil may be elliptical in shape. Similarly, as shown in FIG. 36 or FIG. 37, each etendue gate or exit pupil may be rectangular or hexagonal. Other shapes for the etendue gates and exit pupils are possible, alone or in combination, such as in cases like those illustrated above where multiple etendue gates and/or exit pupils are combined within a single emitter system.

The following statements are intended to cover generic and specific features described herein. In particular, the following embodiments are contemplated, as well as any combinations of such embodiments:

1. Each cavity disclosed herein may include one or more emitters therein. In such a case, adjacent cavities may or may not be fully optically isolated from each other. For instance, according to the requirements of a given application, some amount of adjacent-cavity optical interaction may be desirable for anti-aliasing or brightness/efficiency reasons.

2. Each cavity disclosed herein may include one or more exit apertures.

3. Each lenslet disclosed herein may be configured to direct light from one or more cavities.

4. The forward-facing external surface of any etendue gate disclosed herein (i.e., the surface facing the mode-matching optics) may include at least one of an absorptive, low-reflection, no-reflection, or other anti-reflective coating to enhance the display contrast when there is external light shining on the emitter. Such mechanisms to control reflections from the etendue gate may be included in the emitter system with or without subsequent mode-matching optics or lenslets.

5. Any etendue gate disclosed herein may include a polarizer such that the emitter system provides a polarized light output. In an example, the polarizer may be configured to transmit light of a first polarization state therethrough while reflecting a second polarization back into the cavity, thus providing a polarized light output with increased efficiency over an absorptive polarizer.

### Combination of Features

Features described above as well as those claimed below may be combined in various ways without departing from the scope hereof. The following enumerated examples illustrate some possible, non-limiting combinations:

(A1) An emitter system assembly for providing a light output for a projector includes: an emitter providing a light emission; a cavity at least partially surrounding the emitter; an aperture configured for transmitting therethrough at least a portion of the light emission from the emitter; and a lenslet in optical communication with the aperture, wherein the cavity includes reflectors for reflecting the light emission within the cavity and toward the aperture, and wherein the cavity, the aperture, and the lenslet are configured to cooperate to produce the light output having optical properties suitable for coupling into the projector.

(A2) In embodiments of (A1), the cavity, the aperture, and the lenslet are configured to produce the light output having at least one of a predetermined output direction and a solid angle.

(A3) Either one of embodiments (A1) or (A2) further include a second emitter for providing a second light emission.

(A4) In any one of embodiments (A1)-(A3), the emitter provides the light emission at a first wavelength range, and the second emitter provides the second light emission at a second wavelength range, the second wavelength range being different from the first wavelength range.

(A5) In any one of embodiments (A1)-(A4), the cavity at least partially surrounds both the emitter and the second emitter.

(A6) In any one of embodiments (A1)-(A5), the aperture is configured for transmitting therethrough at least a portion of both the light emission and the second light emission.

(A7) Any one of embodiments (A1)-(A6) further include a second cavity at least partially surrounding the second emitter; a second aperture configured for transmitting therethrough at least a portion of the light emission from the emitter; and a second lenslet in optical communication with the second aperture,

(A8) Any one of embodiments (A1)-(A7) further include a light baffle absorber for at least partially preventing crosstalk between the light output and the second light output.

(A9) Any one of embodiments (A1)-(A8) further include a third emitter for providing a third light emission at a third wavelength range, the third wavelength range being different from the first and second wavelength ranges,

(A10) In any one of embodiments (A1)-(A9), the lenslet is formed of a low refractive index material.

(A11) Any one of embodiments (A1)-(A10) further include an anti-reflective layer on the lenslet.

(A12) Any one of embodiments (A1)-(A11) further include light containment structures around the emitter.

(A13) In any one of embodiments (A1)-(A12), the light containment structures include at least one of a reflective layer and a dielectric Bragg reflector.

(B1) An emitter system assembly for providing a light output for a projector includes: a first emitter providing a first light emission; a second emitter providing a second light emission; a first cavity at least partially surrounding the first emitter; a second cavity at least partially surrounding the second emitter; a first aperture configured for transmitting therethrough at least a portion of the first light emission from the first emitter; a second aperture configured for transmitting therethrough at least a portion of the second light emission from the second emitter; and a lenslet in optical communication with the first and second apertures, wherein the first cavity includes first reflectors for reflecting the first light emission within the first cavity and toward the first aperture, wherein the second cavity includes second reflectors for reflecting the second light emission within the second cavity and toward the second aperture, and wherein the first cavity, the first aperture, the second cavity, the second aperture, and the lenslet are configured to cooperate to produce the first and second light emission to contribute to the light output having optical properties suitable for coupling into the projector.

(B2) In embodiments of (B1), the first cavity, the first aperture, the second cavity, the second aperture, and the lenslet are configured to produce the light output having at least one of a predetermined output direction and a solid angle.

(B3) Either one of embodiments (B1) or (B2) further include a light baffle absorber for preventing crosstalk between the first and second cavities.

(C1) An emitter system assembly for providing light output for a projector includes: a first emitter providing a first light emission; a second emitter providing a second light emission; a cavity at least partially surrounding the first and second emitters; an aperture configured for transmitting therethrough at least a portion of the first and second light emission from the first and second emitters; and a lenslet in optical communication with the aperture, wherein the cavity includes reflectors for reflecting the first and second light emissions within the cavity and toward the aperture, and wherein the cavity, the aperture, and the lenslet are configured to cooperate to produce the light output having optical properties suitable for coupling into the projector.

(C2) In embodiments of (C1), the cavity, the aperture, and the lenslet are configured to produce the light output having at least one of a predetermined output direction and a solid angle.

(D1) A method for forming an emitter system assembly includes: forming an emitter array on an emitter substrate; attaching the emitter substrate to a backplane; forming an array of cavities and an array of apertures aligned with the emitter array; and attaching a lenslet array, aligned with the array of apertures.

(D2) Method (D1) further includes removing the emitter substrate while the emitter array remains attached to the backplane.

Accordingly, although the present disclosure has been provided in accordance with the implementations shown, one of ordinary skill in the art will readily recognize that there could be variations to the embodiments and those variations would be within the scope of the present disclosure. Therefore, many modifications may be made by one of ordinary skill in the art without departing from the scope of the appended claims.

1. An emitter system assembly for providing a light output for a projector, the emitter system assembly comprising:
an emitter providing a light emission;
a cavity at least partially surrounding the emitter;
an aperture configured for transmitting therethrough at least a portion of the light emission from the emitter; and
a lenslet in optical communication with the aperture,
wherein the cavity includes reflectors for reflecting the light emission within the cavity and toward the aperture, and
wherein the cavity, the aperture, and the lenslet are configured to cooperate to produce the light output having optical properties suitable for coupling into the projector.

2. The emitter system assembly of claim 1, wherein the cavity, the aperture, and the lenslet are configured to produce the light output having at least one of a predetermined output direction and a solid angle.

3. The emitter system assembly of claim 1, further comprising a second emitter for providing a second light emission.

4. The emitter system assembly of claim 3,
wherein the emitter provides the light emission at a first wavelength range, and
wherein the second emitter provides the second light emission at a second wavelength range, the second wavelength range being different from the first wavelength range.

5. The emitter system assembly of claim 3, wherein the cavity at least partially surrounds both the emitter and the second emitter.

6. The emitter system assembly of claim 3, wherein the aperture is configured for transmitting therethrough at least a portion of both the light emission and the second light emission.

7. The emitter system assembly of claim 3, further comprising
a second cavity at least partially surrounding the second emitter;
a second aperture configured for transmitting therethrough at least a portion of the light emission from the emitter; and
a second lenslet in optical communication with the second aperture,
wherein the second emitter, the second cavity, the second aperture, and the second lenslet are configured to produce a second light output having optical properties suitable for coupling into the projector.

8. The emitter system assembly of claim 7, further comprising a light baffle absorber for at least partially preventing crosstalk between the light output and the second light output.

9. The emitter system assembly of claim 4, further comprising a third emitter for providing a third light emission at a third wavelength range, the third wavelength range being different from the first and second wavelength ranges,
wherein the aperture is configured for transmitting therethrough at least a portion of the light emission, the second light emission, and the third light emission.

10. The emitter system assembly of claim 1, the lenslet being formed of a low refractive index material.

11. The emitter system assembly of claim 1, further comprising an anti-reflective layer on the lenslet.

12. The emitter system assembly of claim 1, further comprising light containment structures around the emitter.

13. The emitter system assembly of claim 12, wherein the light containment structures include at least one of a reflective layer and a dielectric Bragg reflector.

14. An emitter system assembly for providing a light output for a projector, the emitter system assembly comprising:
a first emitter providing a first light emission;
a second emitter providing a second light emission;
a first cavity at least partially surrounding the first emitter;
a second cavity at least partially surrounding the second emitter;
a first aperture configured for transmitting therethrough at least a portion of the first light emission from the first emitter;
a second aperture configured for transmitting therethrough at least a portion of the second light emission from the second emitter;
and a lenslet in optical communication with the first and second apertures,
wherein the first cavity includes first reflectors for reflecting the first light emission within the first cavity and toward the first aperture,
wherein the second cavity includes second reflectors for reflecting the second light emission within the second cavity and toward the second aperture, and
wherein the first cavity, the first aperture, the second cavity, the second aperture, and the lenslet are configured to cooperate to produce the first and second light emission to contribute to the light output having optical properties suitable for coupling into the projector.

15. The emitter system assembly of claim 14, wherein the first cavity, the first aperture, the second cavity, the second aperture, and the lenslet are configured to produce the light output having at least one of a predetermined output direction and a solid angle.

16. The emitter system assembly of claim 14, further comprising a light baffle absorber for preventing crosstalk between the first and second cavities.

17. An emitter system assembly for providing light output for a projector, the emitter system assembly comprising:
a first emitter providing a first light emission;
a second emitter providing a second light emission;
a cavity at least partially surrounding the first and second emitters;
an aperture configured for transmitting therethrough at least a portion of the first and second light emission from the first and second emitters; and
a lenslet in optical communication with the aperture,
wherein the cavity includes reflectors for reflecting the first and second light emissions within the cavity and toward the aperture, and
wherein the cavity, the aperture, and the lenslet are configured to cooperate to produce the light output having optical properties suitable for coupling into the projector.

18. The emitter system assembly of claim 17, wherein the cavity, the aperture, and the lenslet are configured to produce the light output having at least one of a predetermined output direction and a solid angle.

19. A method for forming an emitter system assembly, the method comprising:
forming an emitter array on an emitter substrate;
attaching the emitter substrate to a backplane;
forming an array of cavities and an array of apertures aligned with the emitter array; and
attaching a lenslet array, aligned with the array of apertures.

20. The method of claim 19, further comprising, after attaching the emitter substrate to the backplane, removing the emitter substrate while the emitter array remains attached to the backplane.
